(19) United States
(12) Patent Application Publication
(10) Pub. No.: US 2023/0034192 A1
(43) Pub. Date: Feb. 2, 2023

(54) Systems and Methods for Transient Thermal Process Simulation in Complex Subsurface Fracture Geometries

(71) Applicants: Sim Tech LLC, Katy, TX (US); Board of Regents, The University of Texas System, Austin, TX (US)

(72) Inventors: Kamy Sepehrnoori, Austin, TX (US); He Sun, Austin, TX (US); Wei Yu, College Station, TX (US); Jijun Miao, Katy, TX (US)

(73) Assignees: Sim Tech LLC, Katy, TX (US); Board of Regents, The University of Texas System, Austin, TX (US)

(21) Appl. No.: 17/375,140

(22) Filed: Jul. 14, 2021

(51) Int. Cl. G01V 99/00; G06F 30/20

(52) U.S. Cl. CPC G01V 99/005; G06F 30/20

(57) ABSTRACT

Systems and methods for simulating subterranean regions having multi-scale, complex fracture geometries. Non-intrusive embedded discrete fracture modeling formulations are applied in conjunction with commercial or in-house simulators to efficiently and accurately model subsurface characteristics including temperature profiles in regions having complex hydraulic fractures, complex natural fractures, or a combination of both.

### FIELD OF THE INVENTION

The present disclosure relates generally to methods and systems for the simulation of subterranean regions with multi-scale complex fracture geometries, applying non-intrusive embedded discrete fracture modeling formulations with simulators.

### BACKGROUND

The recovery of natural resources (e.g., oil, gas, geothermal steam, water, coal bed methane) from subterranean formations is often made difficult by the nature of the rock matrix in which they reside. Some formation matrices have very limited permeability. Such “unconventional” subterranean regions include shale reservoirs, siltstone formations, and sandstone formations. Technological advances in the areas of horizontal drilling and multi-stage hydraulic fracturing have improved the development of unconventional reservoirs. Hydraulic fracturing is a well stimulation technique used to increase permeability in a subterranean formation. In the fracturing process, a fluid is pumped into casing lining the wellbore traversing the formation. The fluid is pumped in at high pressure to penetrate the formation via perforations formed in the casing. The high-pressure fluid creates fissures or fractures that extend into and throughout the rock matrix surrounding the wellbore. Once the fractures are created, the fluids and gases in the formation flow more freely through the fractures and into the wellbore casing for recovery to the surface.

Since the presence of fractures significantly impacts the flow behavior of subterranean fluids and gases, it is important to accurately model or simulate the geometry of the fractures in order to determine their influence on well performance and production optimization. The design and effectiveness of a hydraulic fracturing operation largely determines the economy of an unconventional reservoir. Consequently, many fracture diagnostic tools, such as micro-seismic, distributed temperature sensing, distributed acoustic sensing, tracer flow-back tests, and diagnostic fracture injection tests, have been developed to better design the operation parameters and evaluate the performance of the hydraulic fracturing operation.

Most of the research on unconventional reservoirs is based on an isothermal assumption. However, due to cool fracturing fluid injection during the fracturing stage and the Joule-Thompson (JT) effect during the production stage, temperature distribution, especially for the near-wellbore region, can experience obvious changes. The temperature variance causes thermal-induced stress within the rock region, which generates thermal fractures.

Enhanced Geothermal Systems (EGS) have gained great attention since they deliver geographically disperse, carbon-free energy without the environmental impact. Thermal fracture networks have also significantly contributed to the energy extraction of EGS. The novel fracture diagnosis tool (DTS) relies on the thermal field of the fracture network. Although several analytical or numerical models have been developed for DTS and EGS, a challenging problem persists in modelling realistic fractures with three-dimensional complex hydraulic and natural fracture networks. Thus, a need remains for improved thermal modeling techniques to efficiently and accurately model multi-scale complex subsurface fracture networks.

### SUMMARY

According to an aspect of the invention, a system for simulating a subterranean region having fracture geometries is disclosed. This embodiment includes at least one processor to execute instructions to perform functions including to: input data representing the subterranean region and comprising matrix grid data and parameters associated with fractures in the subterranean region; produce a matrix grid using the input data to identify geometric interactions between fractures and matrix cells in the matrix grid; create a new fracture cell for each segment of a fracture interacting with a matrix cell in the matrix grid; assign physical properties to each new created fracture cell; identify geometric relationships between the new created fracture cells and between the new created fracture cells and the matrix cells; calculate thermal variances between the new created fracture cells and the matrix cells; and generate a simulation of the subterranean region using the calculated thermal variances.

According to another aspect of the invention, a method for simulating a subterranean region having fracture geometries is disclosed. In this embodiment, data representing the subterranean region is obtained, the data comprising matrix grid data and parameters associated with fractures in the subterranean region. The obtained data is used in a computational domain to produce a matrix grid by: identifying geometric interactions between fractures and matrix cells in the matrix grid; creating a new fracture cell for each segment of a fracture interacting with a matrix cell in the matrix grid; assigning physical properties to each new created fracture cell; identifying geometric relationships between the new created fracture cells and between the new created fracture cells and the matrix cells; and calculating thermal variances between the new created fracture cells the matrix cells. A simulation of the subterranean region is generated using the calculated thermal variances.

Other aspects of the embodiments described herein will become apparent from the following description and the accompanying drawings, illustrating the principles of the embodiments by way of example only.

### BRIEF DESCRIPTION OF THE DRAWINGS

The following figures form part of the present specification and are included to further demonstrate certain aspects of the present disclosure and should not be used to limit or define the claimed subject matter. The claimed subject matter may be better understood by reference to one or more of these drawings in combination with the description of embodiments presented herein. Consequently, a more complete understanding of the present embodiments and further features and advantages thereof may be acquired by referring to the following description taken in conjunction with the accompanying drawings, in which like reference numerals may identify like elements, wherein:

FIG. 1A shows a schematic of a subsurface physical domain representation using a formulation for handling complex fractures according to an example of the present disclosure.

FIG. 1B shows a schematic of a computational domain using the formulation for handling the representation in FIG. 1A.

FIG. 2 depicts a schematic illustration of a fracture intersection calculation according to an example of the present disclosure.

FIG. 3 depicts a simulation modeling of a subterranean region according to an example of the present disclosure.

FIG. 4 depicts a simulation modeling of a pressure field in a subterranean region according to an example of the present disclosure.

FIG. 5 depicts a simulation modeling of a temperature field in a subterranean region according to an example of the present disclosure.

FIG. 6A depicts a gas-phase flow profile of the wellbore in a subterranean region according to an example of the present disclosure.

FIG. 6B depicts a water-phase flow profile of the wellbore in a subterranean region according to an example of the present disclosure.

FIG. 6C depicts a temperature profile of the wellbore in a subterranean region according to an example of the present disclosure.

FIG. 7A depicts a simulation modeling of a hydraulic fracture geometry in a subterranean region according to an example of the present disclosure.

FIG. 7B depicts a simulation modeling of a natural fracture geometry in a subterranean region according to an example of the present disclosure.

FIG. 7C depicts a simulation modeling of a complex geometry subterranean region with hydraulic and natural fractures according to an example of the present disclosure.

FIG. 8A depicts a simulation modeling of a temperature distribution profile of a subterranean region with a multi-scale, complex fracture geometry after three years production according to an example of the present disclosure.

FIG. 8B depicts a simulation modeling of a pressure distribution profile of a subterranean region with a multi-scale, complex fracture geometry after three years production according to an example of the present disclosure.

FIG. 8C depicts a simulation modeling of a pressure distribution profile of a subterranean region with a multi-scale, complex fracture geometry after ten years production according to an example of the present disclosure.

FIG. 8D depicts a simulation modeling of a temperature distribution profile of a subterranean region with a multi-scale, complex fracture geometry after ten years production according to an example of the present disclosure.

FIG. 8E depicts a simulation modeling of a pressure distribution profile of a subterranean region with a multi-scale, complex fracture geometry after twenty years production according to an example of the present disclosure.

FIG. 8F depicts a simulation modeling of a temperature distribution profile of a subterranean region with a multi-scale, complex fracture geometry after twenty years production according to an example of the present disclosure.

FIG. 8G depicts a simulation modeling of a pressure distribution profile of a subterranean region near a producer well after twenty years production according to an example of the present disclosure.

FIG. 8H depicts a simulation modeling of a temperature distribution profile of a subterranean region near a producer well after twenty years production according to an example of the present disclosure.

FIG. 8I depicts a simulation modeling of a pressure distribution profile of a subterranean region near an injector well after twenty years production according to an example of the present disclosure.

FIG. 8J depicts a simulation modeling of a temperature distribution profile of a subterranean region near an injector well after twenty years production according to an example of the present disclosure.

FIG. 9A depicts a simulation modeling of a temperature distribution profile of a subterranean matrix after three years production according to an example of the present disclosure.

FIG. 9B depicts a simulation modeling of a pressure distribution profile of a subterranean matrix after three years production according to an example of the present disclosure.

FIG. 9C depicts a simulation modeling of a pressure distribution profile of a subterranean matrix after ten years production according to an example of the present disclosure.

FIG. 9D depicts a simulation modeling of a temperature distribution profile of a subterranean matrix after ten years production according to an example of the present disclosure.

FIG. 9E depicts a simulation modeling of a pressure distribution profile of a subterranean matrix after twenty years production according to an example of the present disclosure.

FIG. 9F depicts a simulation modeling of a temperature distribution profile of a subterranean matrix after twenty years production according to an example of the present disclosure.

FIG. 9G depicts a simulation modeling of a pressure distribution profile of a subterranean matrix near a producer well after twenty years production according to an example of the present disclosure.

FIG. 9H depicts a simulation modeling of a temperature distribution profile of a subterranean matrix near a producer well after twenty years production according to an example of the present disclosure.

FIG. 9I depicts a simulation modeling of a pressure distribution profile of a subterranean matrix near an injector well after twenty years production according to an example of the present disclosure.

FIG. 9J depicts a simulation modeling of a temperature distribution profile of a subterranean matrix near an injector well after twenty years production according to an example of the present disclosure.

FIG. 10A depicts a simulation modeling of a cooling zone propagation profile of a subterranean region with a multi-scale, complex fracture geometry after three years production according to an example of the present disclosure.

FIG. 10B depicts a simulation modeling of a cooling zone propagation profile of a subterranean region with a multi-scale, complex fracture geometry after ten years production according to an example of the present disclosure.

FIG. 10C depicts a simulation modeling of a cooling zone propagation profile of a subterranean region with a multi-scale, complex fracture geometry after twenty years production according to an example of the present disclosure.

FIG. 11 shows a plot of a temperature profile of a producer well over twenty years of production.

FIG. 12 depicts a system for simulating a subterranean region with complex fracture geometries according to an example of the present disclosure.

### DETAILED DESCRIPTION

The foregoing description of the figures is provided for the convenience of the reader. It should be understood, however, that the embodiments are not limited to the precise arrangements and configurations shown in the figures. In the development of any actual embodiment, numerous implementation-specific decisions may need to be made to achieve the design-specific goals, which may vary from one implementation to another. It will be appreciated that such a development effort, while possibly complex and time-consuming, would nevertheless be a routine undertaking for persons of ordinary skill in the art having the benefit of this disclosure.

Embodiments of this disclosure present efficient techniques to model subterranean regions with complex geometries entailing thermal simulation. Through non-neighboring connections (NNCs), an embedded discrete fracture modeling (EDFM) formulation is applied to data representing a subterranean region to accurately model or simulate formations with complex geometries such as fracture networks and nonplanar fractures. The data representing the subterranean region to be modeled may be obtained by conventional means as known in the art, such as formation evaluation techniques, reservoir surveys, seismic exploration, etc. The subterranean region data may comprise information relating to the fractures, the reservoir, and the wells, including number, location, orientation, length, height, aperture, permeability, reservoir size, reservoir permeability, reservoir depth, well number, well radius, well trajectory, temperature, etc. EDFM modeling techniques are further describe in U.S. Pat. No. 10,914,140, assigned to the present assignees. The entire contents of U.S. Pat. No. 10,914,140 are hereby incorporated by reference into this disclosure.

Some embodiments utilize data representing the subterranean region produced by conventional reservoir simulators as known in the art. Conventional simulators are designed to generate models of subterranean regions, producing data sets including a matrix grid, fracture parameters, well parameters, and other parameters related to the specific production or operation of the particular field or reservoir. Embodiments of this disclosure provide a non-intrusive application of an EDFM formulation that allows for insertion of discrete fractures into a computational domain and the use of a simulator's original functionalities without requiring access to the simulator source code. The embodiments may be easily integrated into existing frameworks for conventional or unconventional reservoirs to perform various analyses as described herein.

### I Flow and Thermal Field Modeling of Complex Fracture Networks

Embodiments of this disclosure employ an approach that creates fracture cells in contact with corresponding matrix cells to account for the heat transfer between continua. Once a fracture interacts with a matrix cell (e.g., fully or partially penetrating a matrix cell), a new additional cell is created to represent the fracture segment in the physical domain. The individual fractures are discretized into several fracture segments by the matrix cell boundaries. To differentiate the newly added cells from the original matrix cells, these additional cells are referred to herein as “fracture cells.”

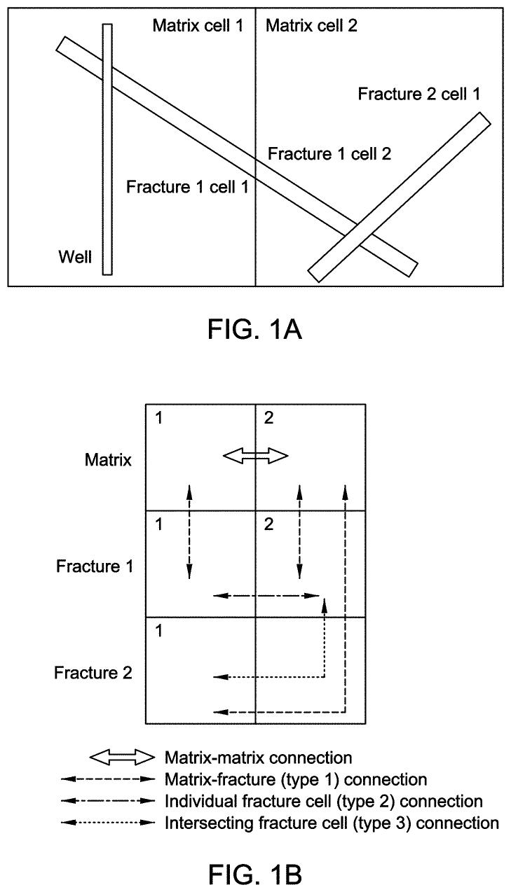

FIG. 1A depicts the procedure to implement fracture cells in the EDFM using a simple case with only two matrix cells and two fractures. FIG. 1A depicts the physical domain top view of a reservoir with two fractures intersecting each other. FIG. 1B depicts the corresponding computational domain schematic. In this exemplary embodiment, the physical domain includes two matrix cells, two inclined fractures, and one wellbore. The computational domain includes two matrix cells: cell 1 and cell 2. Fracture 1 intersects two matrix cells and is discretized into two fracture segments. Fracture 2 lies in one matrix cell and is discretized into one fracture segment. One new extra fracture cell (null cell) is introduced in the computational domain to maintain a structured grid. The depth of each fracture cell is defined as the depth of the centroid of the corresponding fracture segment.

In constructing the convective and conductive heat flow between the created fracture cells and surrounding matrix cells, the disclosed embodiments postulate that: 1) pressure gradient is symmetric to the fracture surface; 2) pressure changes on both sides of the fracture are linear; 3) temperature gradient is symmetric to the fracture surface; and 4) temperature changes on both sides of the fracture are linear. Based on these postulates of thermal flow, a fine mesh can be used near the fracture surface since the pressure and temperature gradient are approximated as linear and symmetric in a small area.

As shown in FIG. 1B, three types of Non-Neighbor Connections (NNC) are applied:
d) Type 1: NNC between fracture cells and matrix cells
e) Type 2: NNC between fracture cells within an individual fracture
f) Type 3: NNC between intersecting fracture cells.
   The NNC conveys the convective and conductive heat flow between the fracture cell and matrix cell.

### II Modeling Flow and Thermal Field in Reservoir Matrix

The reservoir model embodiments of this disclosure are non-isothermal, equation-of-state (EOS) IMPEC (Implicit Pressure and Explicit Composition) compositional models. The material balance equation is discretized with a finite-difference scheme. The general mass conservation equation for each component i can be represented as

$$\frac{\partial }{\partial t} [ ϕ {\sum }_{j = 1}^{{N}_{p}} {S}_{j} {ξ}_{j} {x}_{ij} ] - \vec{▽} \cdot [ {\sum }_{j = 1}^{{N}_{p}} {ξ}_{j} {x}_{ij} \frac{\vec{\vec{k}} {k}_{rj}}{{μ}_{j}} ( ▽ {p}_{j} - {γ}_{j} ▽ D ) ] - \frac{{q}_{i}}{{V}_{b}} = 0 , \qquad ( 1 )$$

where t is time, ϕ is porosity, Nₚ denotes the number of phases (embodiments may handle multiple flow phases), V_{b} is bulk volume, subscript j refers to fluid phases, S is fluid phase saturation, ξ is molar density, x is the mole fraction of component in phase, \vec{\vec{k}} is permeability tensor, kᵣ is relative permeability; μ is phase viscosity, D is depth, γ is specific gravity, p is pressure, and q is molar injection or production rate (positive for injection, negative for production).

Since the IMPEC solution scheme is employed in a reservoir model, the pressure in each grid block is solved in advance. Assuming the pore volume is completely filled with the fluid and the formation rock is slightly compressible:

Vₜ(P,\vec{N})=Vₚ(P), (2)

where Vₜ denotes total fluid volume, and Vₚ refers to pore volume. With differentiating both volumes with respect to time and the chain rule to expand both terms against their independent variables, the final form of pressure equation is rearranged as

$$( {V}_{P}^{0} {c}_{f} - \frac{\partial {V}_{t}}{\partial p} ) \frac{\partial p}{\partial t} - {V}_{b} {\sum }_{i = 1}^{{N}_{c} + 1} {\vec{V}}_{ti} \vec{▽} \cdot {\sum }_{j = 1}^{{N}_{p}} {ξ}_{j} {x}_{ij} \frac{\vec{\vec{k}} {k}_{rj}}{{μ}_{j}} ▽ p = {V}_{b} {\sum }_{i = 1}^{{N}_{c} + 1} {\vec{V}}_{ti} \vec{▽} \cdot {\sum }_{j = 1}^{{N}_{p}} {ξ}_{j} {x}_{ij} \frac{\vec{\vec{k}} {k}_{rj}}{{μ}_{j}} ( ▽ {p}_{cj} - {γ}_{j} ▽ D ) + {\sum }_{i = 1}^{{N}_{c} + 1} {\vec{V}}_{ti} {q}_{i} , \qquad ( 3 )$$

where N_{c} refers to the number of hydrocarbon components, V_{P}⁰ is pore volume at reference pressure, p is the pressure of the reference phase (oleic phase), \vec{V}ₜ is partial molar volume, and p_{cj} is the capillary pressure between phase j and the reference phase.

The energy conservation equation is expressed in enthalpy formation. By solving the enthalpy of each grid block, the temperature profile of the reservoir is obtained. The thermal balance is

$${V}_{b} \frac{\partial {U}^{T}}{\partial t} + {V}_{b} ▽ {\sum }_{j = 1}^{{N}_{p}} ( {ζ}_{j} {h}_{j} {\vec{v}}_{j} ) - {V}_{b} ▽ \cdot ( {λ}_{T} ▽ T ) = - {\dot{Q}}_{L} + {\dot{q}}_{H} , \qquad ( 4 )$$

where U^{T} is the sum of internal energy of the rock and total fluid per bulk volume, λ_{T} is the effective conductive coefficient, hⱼ is the phase molar enthalpy, ζⱼ is the phase fluid density, ζᵣ is the rock density, T is temperature, uⱼ is the internal energy of phase j, uᵣ is the internal energy of the rock, Sⱼ is the saturation of the phase j, [symbol] ⱼ is the phase flux, [symbol] _{L} is the heat loss, \dot{q}_{H} is the enthalpy of the injection fluid, [symbol] ᵣ is the heat of reaction, and the dot in the equation stands for rate.

At each time step, the pressure is solved implicitly with Equation (3) first. Subsequently, the overall number of moles for each component is calculated with mass conservation Equation (1). Finally, the temperature is solved implicitly with the energy balance equation. During the solution process, the saturation of each phase can be acquired with flash calculation and fluid properties obtained with the Peng-Robinson equation of state.

### III Matrix-Fracture Connection (Type 1 NNC)

The heat flow between matrix and fracture is both convective and conductive. The convective heat flow refers to the energy transport carried by the fluid flow perpendicular to the fracture surface. The general convective flow expression is

q_{conv}=T_{NNC}λΔPH, (5)

where H is the enthalpy of the upstream grid block, ΔP is the pressure difference of grid blocks in NNC, and T_{NNC} is the flow transmissibility of NNC. For Type 1 NNC, the T_{NNC} is calculated as

$${T}_{NNC 1} = \frac{2 {A}_{f} ( K \cdot \vec{n} ) \cdot \vec{n}}{{d}_{NNC 1}} , \qquad ( 6 )$$

where A_{f} is the area of the contact surface between matrix and fracture segment on one side, K is the matrix permeability tensor, \vec{n} is the normal vector of the fracture-matrix contact surface, and d_{NNC1} is the average normal distance from the matrix to fracture, which is calculated as

$${d}_{NNC 1} = \frac{{\int }_{V} {x}_{n} dV}{V} , \qquad ( 7 )$$

where V is the volume of the matrix cell, dV is the volume element of the matrix cell, and xₙ is the distance from the volume element to the fracture plane.

Since H in Equation (5) is the average enthalpy of the upstream grid block, small size grid blocks are preferred near the fracture to achieve accuracy. The conductive heat flow is the energy transport between the medium of different temperatures. The conductive flow expression is

q_{cond}=TₜₕΔT, (8)

where Tₜₕ is the thermal conduction factor, which is calculated as

$${T}_{th} = \frac{2 {A}_{f} ( {K}_{th} \cdot \vec{n} ) \cdot \vec{n}}{{d}_{NNC 1}} , \qquad ( 9 )$$

where Kₜₕ is the thermal conductivity of the matrix cell. Generally, the heat flow within an individual fracture or in the intersection of multiple fractures is convective dominant since the flow rate is high. Therefore, for NNC Type 2 and Type 3, only convective heat flow is considered.

### IV Fracture Segment Connection in an Individual Fracture (Type 2)

A fracture can be discretized into multiple segments. The flow transmissibility between neighbor fracture segments is

$${T}_{NNC 2} = \frac{{T}_{1} {T}_{2}}{{T}_{1} + {T}_{2}} \qquad ( 10 a )$$

$${T}_{1} = \frac{{k}_{f} {A}_{c}}{{d}_{seg 1}} , {T}_{2} = \frac{{k}_{f} {A}_{c}}{{d}_{seg 2}} , \qquad ( 10 b )$$

where k_{f} is the fracture permeability, A_{c} is the area of the common face of two fracture segments, and d_{seg} is the distance from the centroid of a fracture cell to the common face.

### V Fracture Intersection (Type 3)

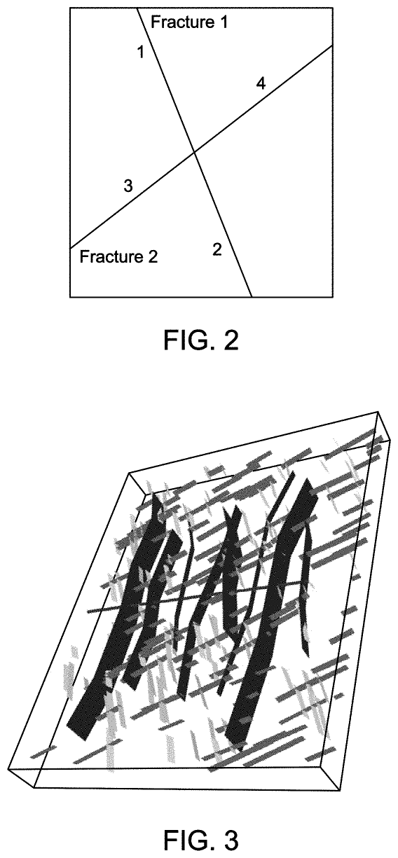

The flow transmissibility in Equation (5) is

$${T}_{NNC 3} = \frac{{T}_{1} {T}_{2}}{{T}_{1} + {T}_{2}} \qquad ( 11 a )$$

$${T}_{1} = \frac{{k}_{f 1} {w}_{f 1} {L}_{i n t}}{{d}_{f 1}} , {T}_{1} = \frac{{k}_{f 2} {w}_{f 2} {L}_{i n t}}{{d}_{f 2}} , \qquad ( 11 b )$$

where Lᵢₙₜ is the length of the intersection line of two fractures, w_{f} is the fracture width, and d_{f} is the weighted average of the normal distances from the centroid of the subsegments to the intersection, which is calculated as

$${d}_{f 1} = \frac{{\int }_{{S}_{1}} {x}_{n} {dS}_{1} + {\int }_{{S}_{2}} {x}_{n} {dS}_{2}}{{S}_{1} + {S}_{2}} , {d}_{f 2} = \frac{{\int }_{S 3} {x}_{n} {dS}_{3} + {\int }_{{S}_{4}} {x}_{n} {dS}_{4}}{{S}_{3} + {S}_{4}} , \qquad ( 12 )$$

where dSᵢ is the area element, Sᵢ is the area of the fracture subsegment cell i as depicted in FIG. 2, and xₙ is the distance from the area element to the intersection line. FIG. 2 schematically depicts the integral calculation. Fracture 1 has two sub-segments, 1 and 2. Fracture 2 has two sub-segments, 3 and 4.

Well-Fracture Connection. The energy source/sink term is

S=WI_{f}(P−BHP)H, (13)

where P is the fracture pressure, BHP is the bottom-hole pressure, H is the enthalpy of fracture cell fluid, and WI_{f} is the well-fracture productivity index, which is calculated as

$${WI}_{f} = \frac{2 π {k}_{f} {w}_{f}}{ln ( \frac{{r}_{e}}{{r}_{w}} )} , {r}_{e} = 0.14 \sqrt{{L}_{S}^{2} + {H}_{S}^{2}} , \qquad ( 14 )$$

where r_{w} is wellbore radius, and Lₛ and Hₛ are the length and height of the fracture segment.

### VI DTS Production Analysis: Complex Hydraulic Fractures with Natural Fracture Network

A simulation study was conducted with embodiments of this disclosure. A multi-phase DTS production analysis with a complex fracture network was conducted. In a first case, both hydraulic and natural fractures with a complex fracture geometry were modeled. Similarly, embodiments of the disclosed comprehensive forward modeling techniques were employed to understand the temperature behavior along the wellbore during the production stage.

FIG. 3 shows the fracture geometry, the location of the horizontal well, and the reservoir domain. There are eight hydraulic fractures (darkened) and two hundred natural fractures (lighter shade). From right to left, the hydraulic fractures are indexed from one to eight. For each hydraulic fracture, the fracture geometry and property are different. Two sets of natural fractures are generated based on Gaussian distribution. The detailed hydraulic and natural fracture geometry and properties are shown in Tables 1 and 2. Table 1 represents the hydraulic fracture height and conductivity for the complex fracture case. Table 2 represents the natural fracture geometry and property for the complex fracture case.

TABLE 1

| | Fracture Index | | | | | | | |
|---|---|---|---|---|---|---|---|---|
| | 1 | 2 | 3 | 4 | 5 | 6 | 7 | 8 |
| Height (ft) | 40 | 80 | 20 | 80 | 40 | 20 | 60 | 80 |
| Conductivity | 12 | 6 | 7 | 5 | 3 | 10 | 6 | 3 |
| (md-ft) | | | | | | | | |

TABLE 2

| Natural | Fracture | Fracture | Fracture | Fracture | Fracture |
|---|---|---|---|---|---|
| Fracture | Length | Height | Conductivity | Angle | dip angle |
| Set Index | (ft) | (ft) | (md-ft) | (°) | (°) |
| 1 | 20-100 | 20-40 | 1-3 | 20-30 | 70-90 |
| 2 | 30-90 | 20-40 | 1-3 | 110-120 | 70-90 |

The reservoir matrix was shale reservoir rock with a low permeability 0.001 mD. The initial water saturation was 0.4 (irreducible water saturation is 0.2). Therefore, there was a water-gas multiphase flow during the production stage. The initial reservoir temperature was 180° F. The wellbore was operated at 1000 psi wellhead pressure. The detailed reservoir and wellbore model input are listed in Tables 3 and 4. Table 3 represents the reservoir model input parameter for the complex fracture case. Table 4 represents the wellbore model input parameter for the complex fracture case.

TABLE 3
Reservoir and Fracture Parameters

| | |
|---|---|
| Reservoir size (ft × ft × ft) | 800 × 1000 × 100 |
| Reservoir permeability (md) | 0.001 |
| Reservoir porosity | 0.1 |
| Initial pore pressure (psi) | 3000 |
| Initial water saturation | 0.4 |
| Initial temperature (° F.) | 180 |
| Rock heat capacity (Btu/ft³-° F.) | 32.397 |
| Rock heat conductivity (Btu/day-ft-° F.) | 42.322 |

TABLE 4
Wellbore Parameters

| | |
|---|---|
| Wellbore length (ft) | 800 |
| Tubing radius (ft) | 0.25 |
| Wellhead pressure (psi) | 1000 |
| Heat transfer coefficient (Btu/hr-ft-° F.) | 1.0 |

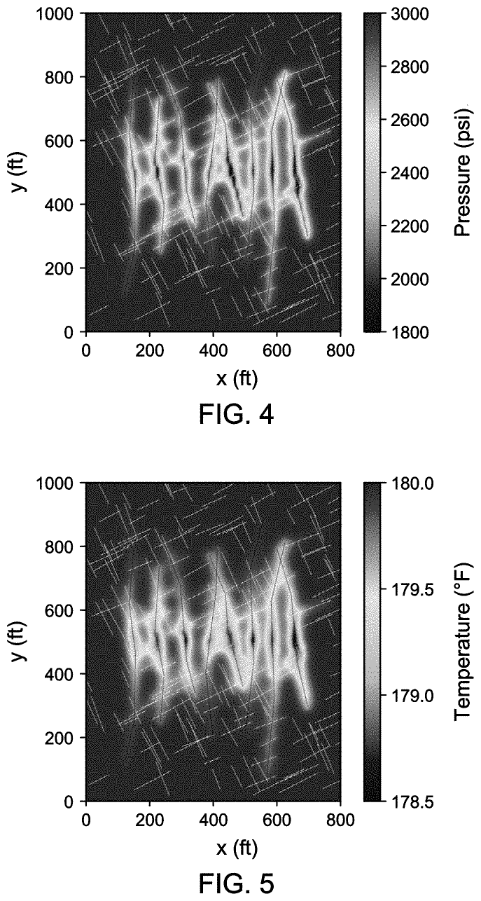

FIG. 4 shows the pressure distribution of the reservoir after sixty days of production. The darkened lines represent the hydraulic fracture geometry. The lighter lines represent the natural fracture geometry. The pressure is depleted around the hydraulic and natural fracture surfaces. Since each hydraulic fracture has different fracture geometry and property, the pressure depletion one is relatively unique for each fracture. The natural fractures connecting to main hydraulic fractures contribute to the pressure depletion. The natural fractures that are connected to the main hydraulic fracture have a trivial contribution to pressure distribution within two months of production. Therefore, the reservoir inflow rate pattern should be, to some degree, sensitive to the natural fracture geometry and property.

FIG. 5 shows the temperature distribution of the reservoir after sixty days of production. The darkened lines represent the hydraulic fracture geometry. The lighter lines represent the natural fracture geometry. The cooling zone propagates around the hydraulic and natural fractures. The temperature drops around the main hydraulic fracture surface. The natural fractures connecting to main hydraulic fractures contribute to the cooling zone. The natural fractures that are connected to the main hydraulic fracture have a trivial contribution to temperature distribution within two months of production. Similarly, the reservoir inflow temperature should be, to some degree, sensitive to the natural fracture geometry and property.

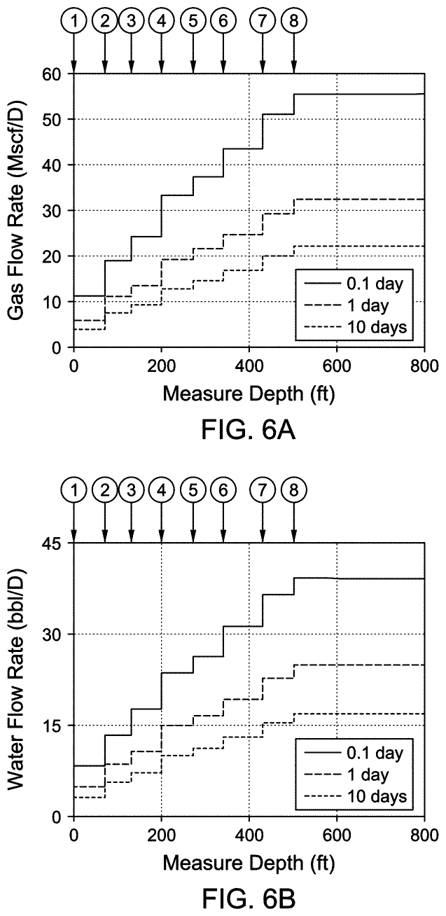

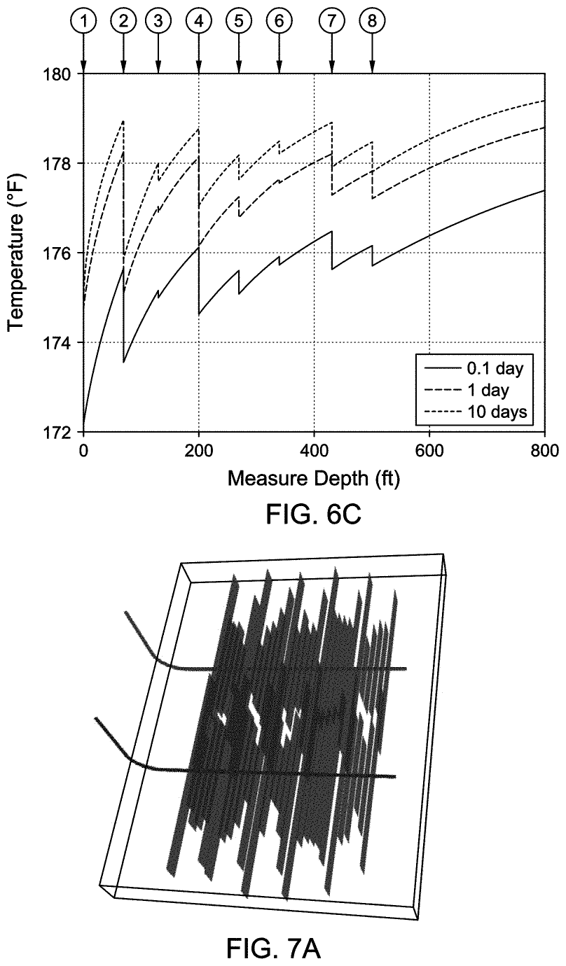

After analyzing the pressure and temperature field of the reservoir with complex hydraulic and natural fractures, it is important to understand the flow profile and temperature behavior with the multiphase flow and complex fractures. FIGS. 6A and 6B respectively show the flow profile of the gas phase and water phase at 0.1 days, 1 day, and 10 days. Each trace represents the flow rate distribution along the wellbore at a certain time. To better understand the flow profile traces, the gas flow profile traces are first analyzed on 0.1 days (black line). At the left end, there is the first reservoir inflow which brings the flow rate level from 0 to almost 10 Mscf/D. When the flow reaches fracture 2, there will be second reservoir inflow coming from fracture 2, which brings the flow rate level from 10 to 20 Mscf/D. Through the difference between the two flow rate levels, the flow rate from each fracture is inferred. Each fracture has a relatively unique inflow rate pattern. For example, the reservoir inflow rate at fracture 5 is smaller than other fractures' inflow rates. Even though the gas and water phase flow profiles are in a different order, the trend for these two-phase flow profiles are almost the same as shown in FIGS. 6A and 6B. FIG. 6A shows the gas flow profile. FIG. 6B shows the water flow profile. The fractures are indexed from one to eight as shown at the top of each graph.

FIG. 6C shows the temperature traces along the wellbore. Each temperature trace represents the temperature distribution along the wellbore. To better understand the flow profile traces, the flow profile traces are first analyzed on 0.1 day (black line). At the left end, there is the first cool reservoir inflow coming from fracture 1 which brings the temperature from initial temperature 180° F. to around 172° F. due to the JT cooling effect. When fluid flows from fracture 1 to fracture 2, the temperature gradually increases just like the single planar case. When the fluid reaches fracture 2, there is the second cool reservoir inflow causing another temperature drop. Therefore, the temperature drop will be observed at every perforation. However, the temperature drop at fracture 3 is less obvious compared to the temperature drop at fracture 2. This is mainly controlled by the mixing effect. When the cool upstream flow from fractures 1 and 2 mixes with new cool reservoir inflow from fracture 3, the cooling effect of the new reservoir inflow will be reduced by the upstream flow. The fracture height and fracture conductivity of fracture 3 are relatively low. Therefore, the reservoir inflow rate will be lower, and the inflow temperature will be higher, which leads to the trivial cooling effect at fracture 3. Therefore, the different combination of fracture geometry and property will define a relative unique DTS data. The DTS data during the production stage is suitable to characterize fracture geometry and property with the disclosed comprehensive model embodiments.

### VII EGS with Two Horizontal Wells

In another simulation with the disclosed embodiments, the temperature behavior of an EGS with one injector well and one producer well was analyzed. The multi-stage hydraulic fracturing operations were conducted for both injector and producer. For each well, there were five stages, each stage having six clusters. The fracture geometry for each stage followed the heel-biased rule. The fracture near the heel had a relative longer fracture length. The fracture near the toe had the second longest fracture length. The fractures in between had a relative short fracture length. Two sets of natural fractures were generated randomly to construct the fracture network between injector and producer.

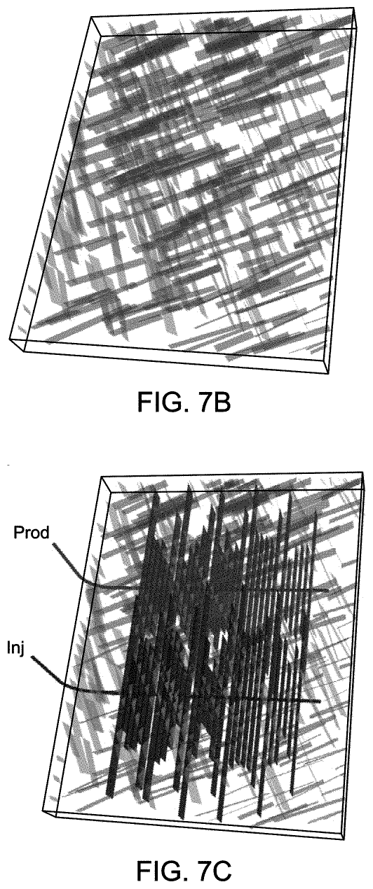

FIGS. 7A-7C show the fracture geometry for both hydraulic and natural fractures, the location of the horizontal wells, and the reservoir domain. FIG. 7A shows the hydraulic fracture geometry. The upper horizontal bar represents the horizontal producer. The lower bar represents the horizontal injector. The planes indicate the multi-stage hydraulic fractures. FIG. 7B shows the natural fracture geometry. The dimension of the tight-gas reservoir model is 1000×1300×120 ft. In this case, a thermal EDFM model embodiment was employed. FIG. 7C shows the hydraulic fractures along the injector and along the producer, in the natural fracture reservoir network. A uniform grid block size 10×10×40 ft was used. The reservoir matrix was hot dry rock with a low permeability 0.0017 mD. The initial water saturation was 1.0, which means the pore volume of the matrix was filled with water. Therefore, there was a single water phase during injection and production. The initial reservoir temperature was 500° F. A horizontal injector and producer penetrate through the center of each hydraulic fracture. The well spacing between the injector and producer was 410 ft. The initial reservoir pressure was 3000 psi. The wellbore was operated at 1500 psi bottom-hole pressure. The injector was operated at 1000 STB/day.

The detailed reservoir and well input are listed in Tables 5 and 6. Table 5 lists the flow parameters for the EGS model setup. Table 6 lists the thermal parameters for the EGS model setup. The detailed heel-biased hydraulic fracture design is listed in Table 7. The statistical input for two sets of natural fracture generation is listed in Table 8. All of the hydraulic fractures and natural fractures were generated randomly based on normal distribution.

TABLE 5
Flow parameter

| Reservoir domain | 1000 × 1300 × 120 | ft |
|---|---|---|
| Reservoir permeability | 0.0017 | mD |
| Initial pressure | 3000 | psi |
| Initial water saturation | 1.0 | |
| Reservoir porosity | 0.2 | |
| Injection rate | 1000 | STB/day |

TABLE 6
Thermal parameter

| | | |
|---|---|---|
| Initial temperature | 500 | ° F. |
| Rock conductivity | 300 | Btu/day-ft-° F. |
| Rock heat capacity | 5.0 | Btu/lb-° F. |
| Injection temperature | 150 | ° F. |

TABLE 7

| Near | | | | |
|---|---|---|---|---|
| Heel | Inner | Near Toe | | |
| Fracture | Fracture | Fracture | | |
| Half- | Half- | Half- | Fracture | Fracture |
| length | length | length | Conductivity | Height |
| (ft) | (ft) | (ft) | (md-ft) | (ft) |
| 360-430 | 100-250 | 300-350 | 10 | 80 |

TABLE 8

| | | | | | Fracture |
|---|---|---|---|---|---|
| Natural | Fracture | Fracture | Fracture | Fracture | dip |
| Fracture | Length | Height | Conductivity | Angle | angle |
| Set Index | (ft) | (ft) | (md-ft) | (°) | (°) |
| 1 | 20-100 | 20-40 | 1-3 | 20-30 | 70-90 |
| 2 | 30-90 | 20-40 | 1-3 | 110-120 | 70-90 |

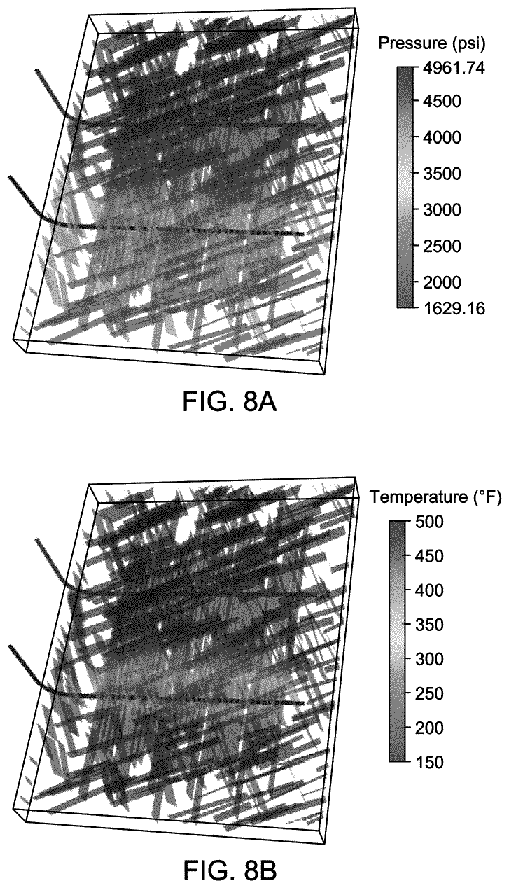

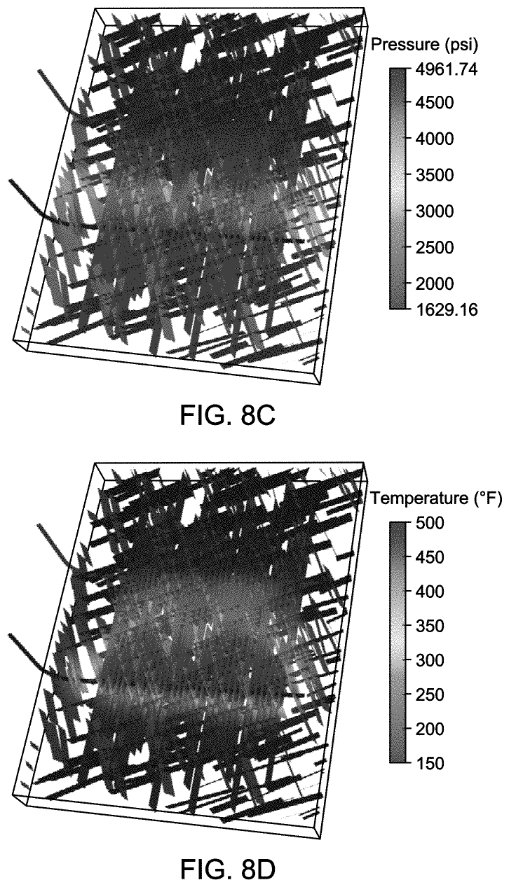

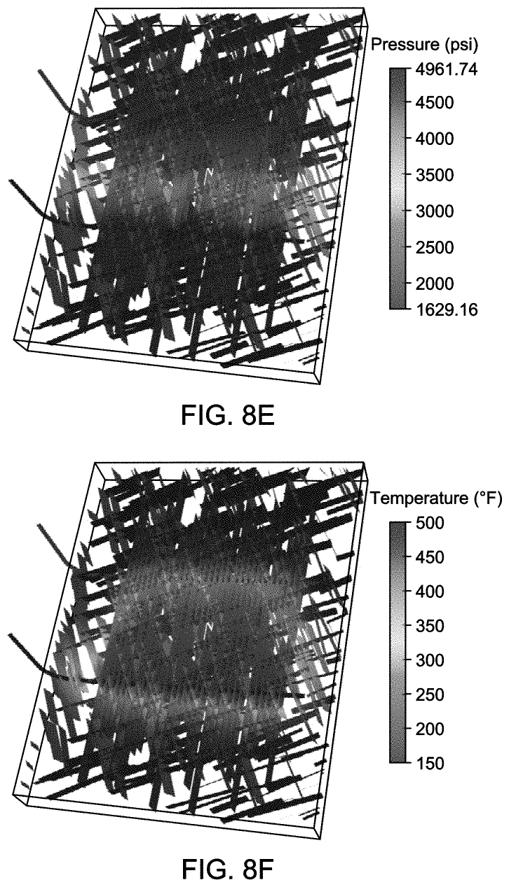

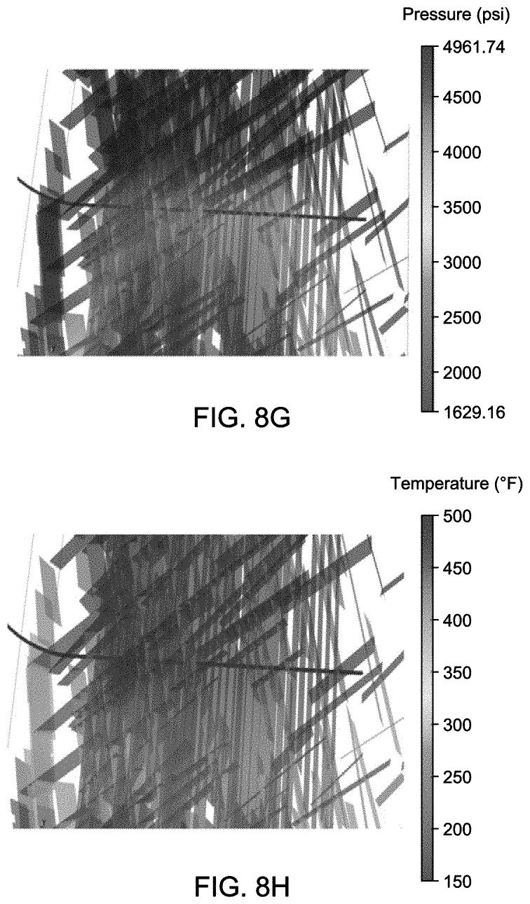

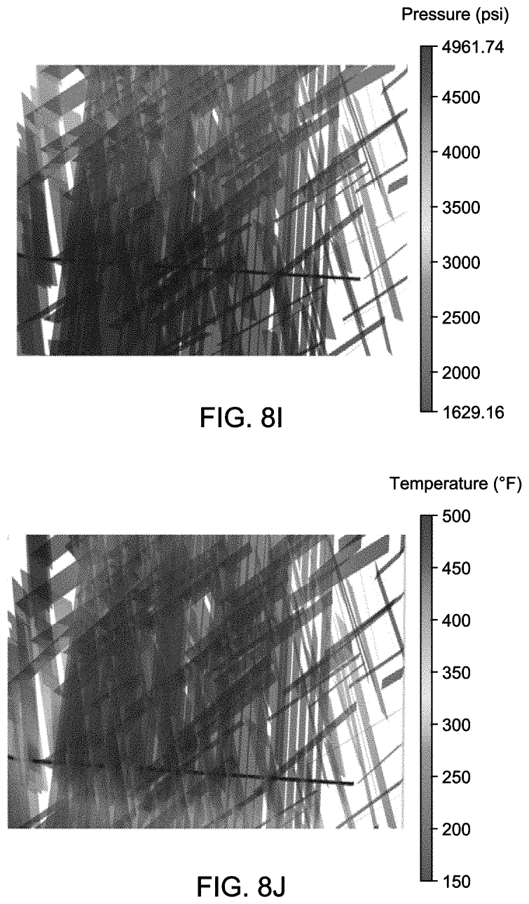

FIGS. 8A-8J show the pressure and temperature distributions within the complex fracture network at 3, 10, and 20 years. For each figure, the 3D fracture geometry for each fracture can be clearly visualized. The shading along each fracture indicates the pressure and temperature distribution inside each fracture. FIGS. 8A, 8C, and 8E respectively show the pressure distribution profile for the complex fracture network at 3, 10, and 20 years. The pressure builds up along the injector trajectory. The pressure gradient and the fracture between injector and producer form the channel for EGS fluid circulation. Through the comparison between the 10 year and 20-year pressure profile, the pressure builds up more severely near the injector. FIGS. 8B, 8D, and 8F respectively show the temperature distribution profile for the complex fracture network at 3, 10, and 20 years. The cool down zone along the fracture path from injector to producer are clearly visible. The cooling zone continues to propagate over time due to the cool water injection. FIGS. 8G and 8I respectively show the zoom-in pressure distribution near the producer and injector after twenty years. FIGS. 8H and 8J respectively show the zoom-in temperature distribution near the producer and injector after twenty years.

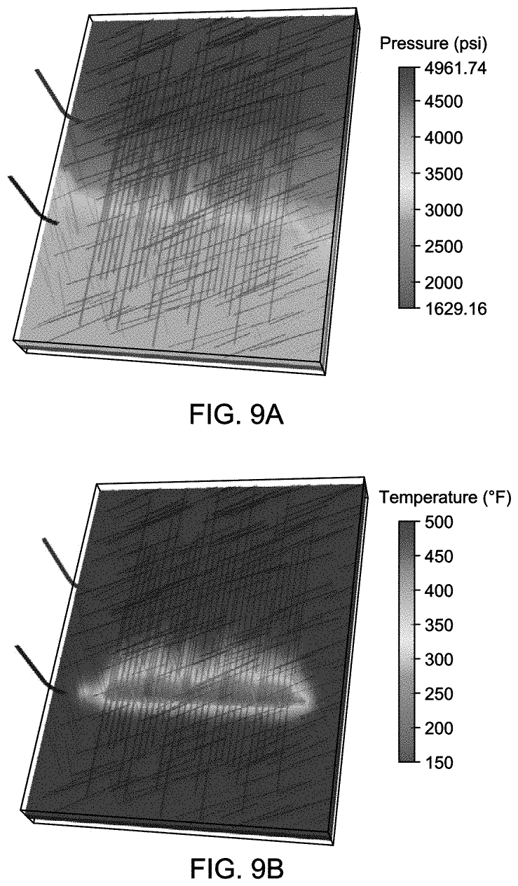

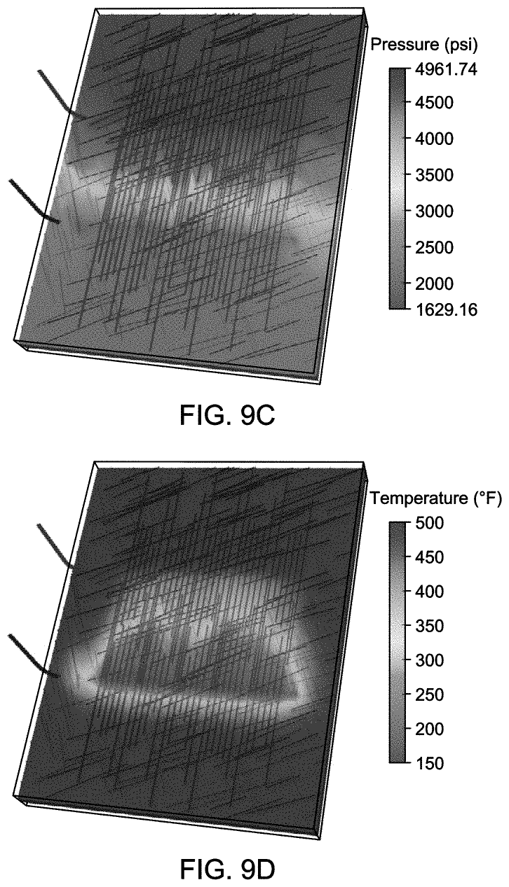

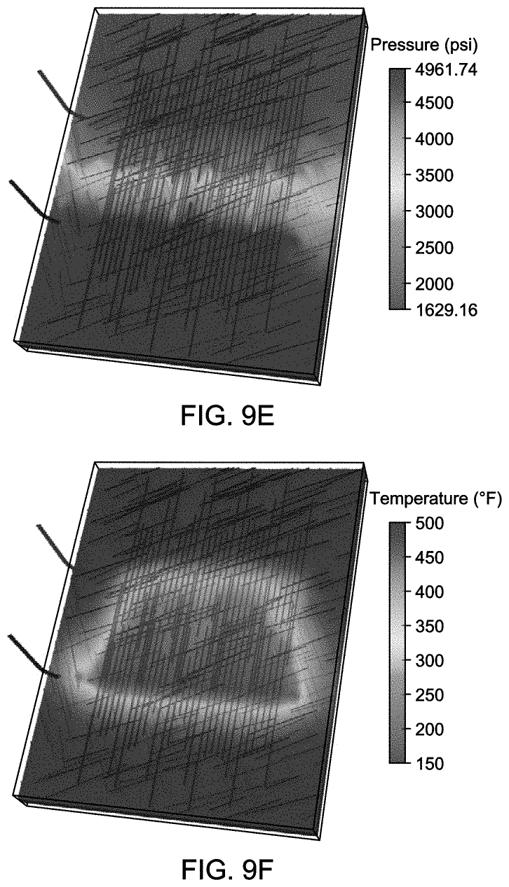

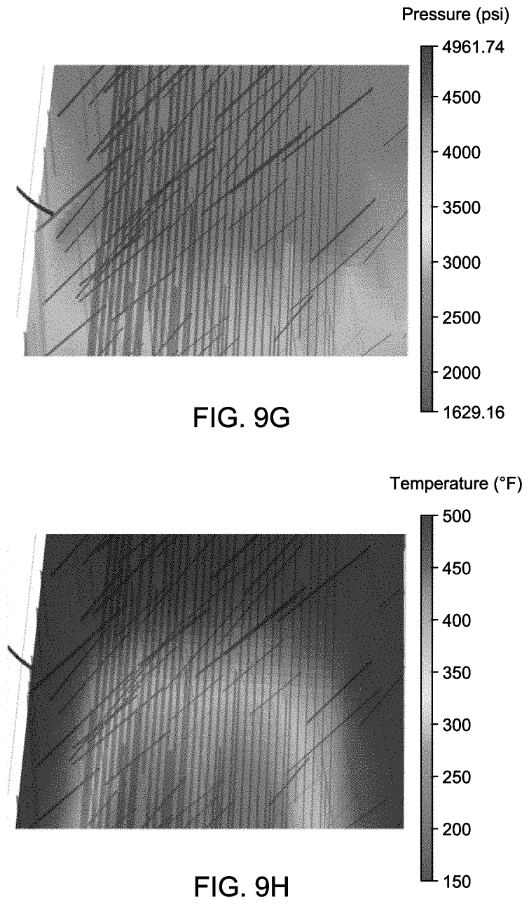

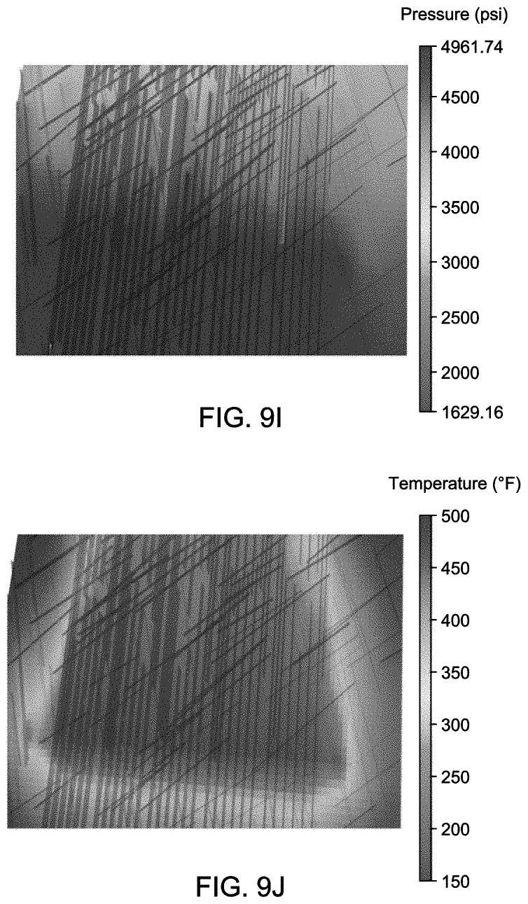

FIGS. 9A-9J show the pressure and temperature distributions in the matrix at 3, 10, and 20 years. Similar patterns can be observed, as in FIGS. 8A-8J. FIGS. 9A, 9C, and 9E respectively show the pressure distribution profile for the complex fracture network at 3, 10, and 20 years The pressure builds up in the matrix near the injector. FIGS. 9B, 9D, and 9F respectively show the temperature distribution profile for the complex fracture network at 3, 10, and 20 years. The cooling zone propagates along the flow path in the matrix rock. FIGS. 9G and 9I respectively show the zoom-in pressure distribution near the producer and injector after twenty years. FIGS. 9H and 9J respectively show the zoom-in temperature distribution near the producer and injector after twenty years.

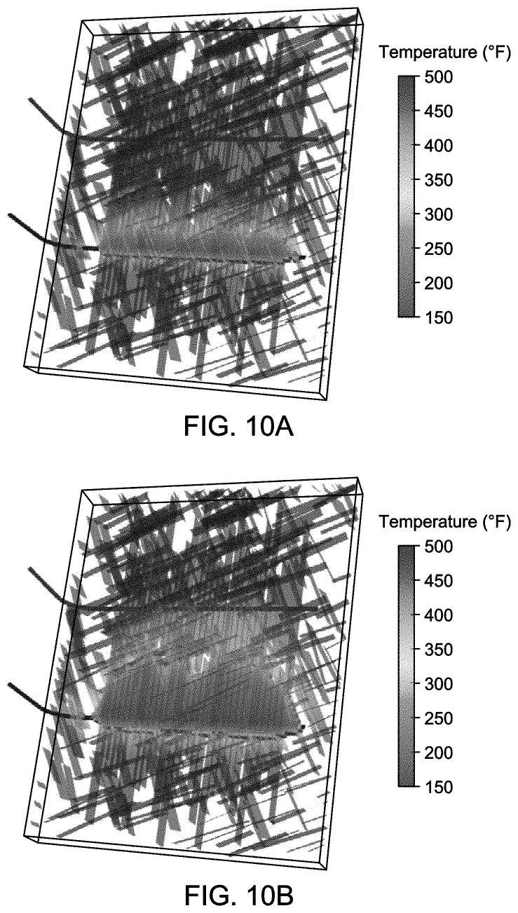

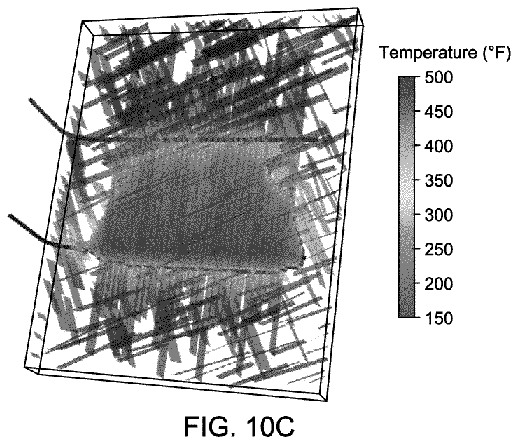

FIGS. 10A-10C respectively show the cooling zone propagation at 3, 10, and 20 years of circulation. At three years, the cooling zone is limited to the surrounding area of the injector. After twenty years, the cooling zone reaches the producer as shown in FIG. 10C.

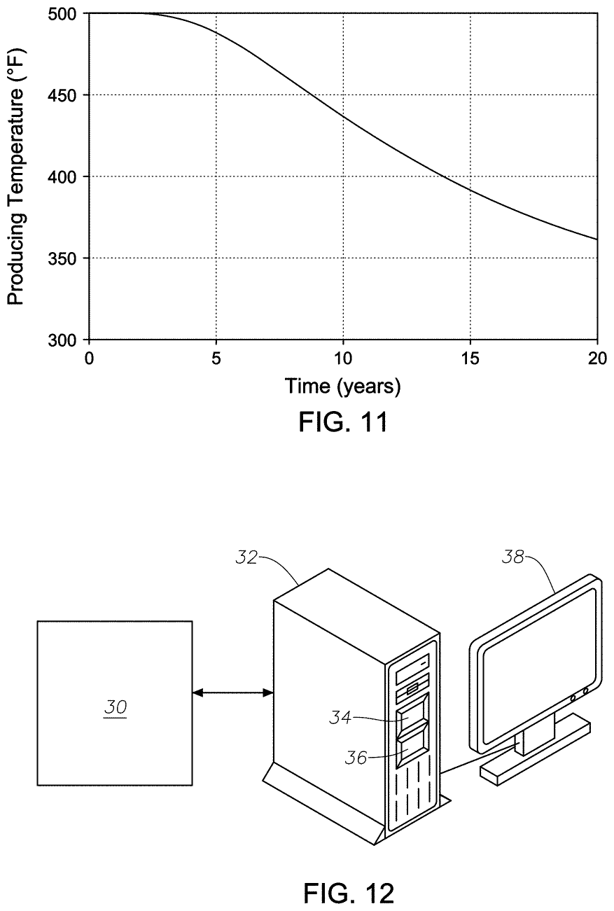

FIG. 11 shows the producing temperature profile of the producer over a twenty year period. Since the initial reservoir temperature is 500° F., the producing temperature stays as initial reservoir temperature before the water breakthrough. At around 2.5 years, the injecting water breaks through the producer and the producing temperature starts to decrease. The producing temperature continue to decrease due to the cool water injection.

Advantages provided by the embodiments of this disclosure include the ability to accurately simulate subsurface characteristics and provide useful data (e.g., fluid flow rates, fluid distribution, fluid saturation, pressure behavior, geothermal activity, well performance, formation distributions, history matching, production forecasting, saturation levels, sensitivity analysis, temperature gradients, etc.), particularly for multi-scale complex fracture geometries. The embodiments are ideal for use in conjunction with commercial simulators or in-house simulators in a non-intrusive or intrusive manner, overcoming key limitations of low computational efficiency and complex gridding issues experienced with conventional methods. The disclosed thermal EDFM techniques can also be applied to analyze the impact of complex fracture network in DTS and EGS. 2D or 3D multi-scale complex fractures can be directly embedded into the matrix grids, including structured grids and unstructured grids.

The EDFM embodiments of this disclosure can handle fractures with any complex boundaries and surfaces with varying roughness. It is common for fractures to have irregular shapes and varying properties (e.g., varying aperture, permeability) along the fracture plane. EDFM embodiments of this disclosure handle different types of structured grids, including Cartesian grids and corner-point grids. The embodiments may be implemented with conventional reservoir simulators or with other applications that generate similar data sets. As a non-intrusive method, the calculations of connection factors, including NNC transmissibility factors and a fracture well index, depend on the gridding, reservoir permeability, thermal conductivity, and fracture geometries.

Embodiments of this disclosure apply a preprocessor to provide the geometrical calculations. Taking the reservoir and gridding information as inputs, the preprocessor performs the calculations disclosed herein and generates an output of data values corresponding to fracture locations, connectivity parameters, geometry parameters, the number of extra grids, the equivalent properties of these grids, transmissibility factors, and NNC pairings. FIG. 12 depicts a system for implementation of embodiments of this disclosure. A simulator module 30 is linked to a computer 32 configured with a microprocessor 34 and memory 36 that can be programmed to perform the steps and processes disclosed herein. The output values calculated by the computer 32 are used as data input (commonly referred to as “keywords”) to the simulator module 30 for generation of the desired simulation. In this manner, the disclosed EDFM formulations are applied in a non-intrusive way in conjunction with conventional simulators with NNC functionality. The EDFM keeps the grids of conventional simulators and models the fractures implicitly through different types of connection factors as described herein, without requiring access to or use of the simulator's source code. Alternatively, some embodiments may be implemented as a unitary application (i.e., wherein one module performs both the simulator and preprocessor functions). A display 38 is linked to the computer 32 to provide a visual output of the simulation results. It will be appreciated by those skilled in the art that conventional software and computer systems may be used to implement the embodiments. It will also be appreciated that programming of the computer 32 and microprocessor 34 can be implemented via any suitable computer language (e.g., PYTHON™, FORTRAN™, C, C++, etc.) in accordance with the techniques disclosed herein. In some embodiments, the simulator module 30 may be remotely located (e.g., at a field site) and linked to the computer 32 via a communication network.

In light of the principles and example embodiments described and illustrated herein, it will be recognized that numerous modifications could be applied to the processes to derive numerous alternative embodiments of the present invention. Items such as applications, modules, components, etc., may be implemented as software constructs stored in a machine accessible storage medium, and those constructs may take the form of applications, programs, subroutines, instructions, objects, methods, classes, or any other suitable form of control logic; such items may also be implemented as firmware or hardware, or as any combination of software, firmware and hardware, or any combination of any two of software, firmware and hardware. It will also be appreciated by those skilled in the art that embodiments may be implemented using conventional memory in applied computing systems (e.g., local memory, virtual memory, and/or cloud-based memory). The term “processor” may refer to one or more processors. What is claimed as the invention, therefore, are all implementations that come within the scope of the following claims, and all equivalents to such implementations.

What is claimed is:

1. A system for simulating a subterranean region having fracture geometries, comprising:
at least one processor to execute instructions to perform functions including to:
input data representing the subterranean region and comprising matrix grid data and parameters associated with fractures in the subterranean region;
produce a matrix grid using the input data to:
identify geometric interactions between fractures and matrix cells in the matrix grid;
create a new fracture cell for each segment of a fracture interacting with a matrix cell in the matrix grid;
assign physical properties to each new created fracture cell;
identify geometric relationships between the new created fracture cells and between the new created fracture cells and the matrix cells;
calculate thermal variances between the new created fracture cells and the matrix cells; and
generate a simulation of the subterranean region using the calculated thermal variances.

2. The system of claim 1 further comprising a simulator module to produce data representing the subterranean region for use as the input data.

3. The system of claim 2 wherein the functions performed by the at least one processor further include functions to input the calculated thermal variances into the simulator module to generate the simulation of the subterranean region.

4. The system of claim 1 wherein the function to identify geometric relationships between the new created fracture cells comprises identification of connections between the new created fracture cells corresponding to the same fracture.

5. The system of claim 1 wherein the function to identify geometric relationships between the new created fracture cells comprises identification of connections between the new created fracture cells corresponding to different fractures.

6. The system of claim 1 wherein the function to identify geometric relationships between the new created fracture cells and between the new created fracture cells and the matrix cells comprises identification of non-neighboring connections.

7. The system of claim 1 wherein the function to generate a simulation of the subterranean region comprises generation of a geometry including at least one of: (i) a complex boundary, (ii) a complex surface, or (iii) a corner point.

8. The system of claim 1 wherein the function to generate a simulation of the subterranean region comprises generation of a temperature profile.

9. The system of claim 1 wherein the function to calculate thermal variances comprises determination of heat flow associated with fluid movement in the subterranean region.

10. The system of claim 1 wherein the function to calculate thermal variances comprises determination of fluid flow between fracture segments in the subterranean region.

11. A method for simulating a subterranean region having fracture geometries, comprising:
obtaining data representing the subterranean region and comprising matrix grid data and parameters associated with fractures in the subterranean region;
in a computational domain, using the obtained data to produce a matrix grid by:
identifying geometric interactions between fractures and matrix cells in the matrix grid;
creating a new fracture cell for each segment of a fracture interacting with a matrix cell in the matrix grid;
assigning physical properties to each new created fracture cell;
identifying geometric relationships between the new created fracture cells and between the new created fracture cells and the matrix cells;
calculating thermal variances between the new created fracture cells the matrix cells; and
generating a simulation of the subterranean region using the calculated thermal variances.

12. The method of claim 11 wherein obtaining data representing the subterranean region comprises obtaining data from a simulator module.

13. The method of claim 12 wherein the computational domain is separate from the simulator module.

14. The method of claim 11 wherein the generating a simulation of the subterranean region comprises inputting the calculated thermal variances into a simulator module to generate the simulation.

15. The method of claim 11 wherein the identifying geometric relationships between the new created fracture cells comprises identifying connections between the new created fracture cells corresponding to the same fracture.

16. The method of claim 11 wherein the identifying geometric relationships between the new created fracture cells comprises identifying connections between the new created fracture cells corresponding to different fractures.

17. The method of claim 11 wherein the identifying geometric relationships between the new created fracture cells and between the new created fracture cells and the matrix cells comprises identifying non-neighboring connections.

18. The method of claim 11, wherein the generating a simulation of the subterranean region comprises generation of a geometry including at least one of: (i) a complex boundary, (ii) a complex surface, or (iii) a corner point.

19. The method of claim 11 wherein the calculating thermal variances comprises determining heat flow associated with fluid movement in the subterranean region.

20. The method of claim 11 wherein the calculating thermal variances comprises determining fluid flow between fracture segments in the subterranean region
